(19) United States
(12) Patent Application Publication
(10) Pub. No.: US 2013/0236697 A1
(43) Pub. Date: Sep. 12, 2013

(54) MICROSTRUCTURED ARTICLES COMPRISING NANOSTRUCTURES AND METHOD

(71) Applicants: Christopher B. Walker, JR., St. Paul, MN (US); Vivian W. Jones, Woodbury, MN (US); Tri D. Pham, Oakdale, MN (US); Joseph T. Aronson, Menomonie, WI (US); Corey D. Balts, Eau Claire, WI (US)

(72) Inventors: Christopher B. Walker, JR., St. Paul, MN (US); Vivian W. Jones, Woodbury, MN (US); Tri D. Pham, Oakdale, MN (US); Joseph T. Aronson, Menomonie, WI (US); Corey D. Balts, Eau Claire, WI (US)

(73) Assignee: 3M INNOVATIVE PROPERTIES COMPANY, St. Paul, MN (US)

(21) Appl. No.: 13/881,524

(22) PCT Filed: Nov. 21, 2011
(86) PCT No.: PCT/US11/61675

§ 371 Date: Apr. 25, 2013

Related U.S. Application Data
(60) Provisional application No. 61/418,643, filed on Dec. 1, 2010.

(51) Int. Cl. G02B 1/11; B81C 1/00

(52) U.S. Cl. CPC G02B 1/11; B81C 1/00444
USPC 428/152; 83/13

(57) ABSTRACT

The present invention concerns microstructured articles comprising nanostructures such an antiglare films, antireflective films, as well as microstructured tools and methods of making microstructured articles.

### BACKGROUND

Various matte films (also described as antiglare films) have been described. A matte film can be produced having an alternating high and low index layer. Such matte film can exhibit low gloss in combination with antireflection. However, in the absence of an alternating high and low index layer, such film would be exhibit antiglare, yet not antireflection.

As described at paragraph 0039 of US 2007/0286994, matte antireflective films typically have lower transmission and higher haze values than equivalent gloss films. For examples the haze is generally at least 5%, 6%, 7%, 8%, 9%, or 10% as measured according to ASTM D1003. Further gloss surfaces typically have a gloss of at least 130 as measured according to ASTM D 2457-03 at 60°; whereas matte surfaces have a gloss of less than 120.

There are several approaches for obtaining matte films.

For example, a matte coating can be prepared by adding matte particles, such as described in U.S. Pat. No. 6,778,240.

Further, matte antireflective films can also be prepared by providing the high and low refractive index layers on a matte film substrate.

In yet another approach, the surface of an antiglare or an antireflective film can be roughened or textured to provide a matte surface. According to U.S. Pat. No. 5,820,957; “the textured surface of the anti-reflective film may be imparted by any of numerous texturing materials, surfaces, or methods. Non-limiting examples of texturing materials or surfaces include: films or liners having a matte finish, microembossed films, a microreplicated tool containing a desirable texturing pattern or template, a sleeve or belt, rolls such as metal or rubber rolls, or rubber-coated rolls.”

US2009/0147361 describes an optical film having a substrate and microreplicated features on a major surface of the substrate. The features include microreplicated macro-scale features and one or more microreplicated diffractive features on the macro-scale features. The films can be made from work pieces machined with tool tips having diffractive features. The tool tip forms both the macro-scale features and diffractive features while machining the work piece. A coating process can then be used to make the optical films from the machined work piece.

### SUMMARY

The present invention concerns microstructured articles comprising nanostructures such an antiglare films, antireflective films, as well as microstructured tools and methods of making microstructured articles.

In some embodiments, antireflective matte films are described having a microstructured surface layer comprising a plurality of microstructures having a complement cumulative slope magnitude distribution such that at least 30% have a slope magnitude of at least 0.7 degrees and at least 25% have a slope magnitude less than 1.3 degrees. The microstructured surface or an opposing surface further comprises nanostructures. In favored embodiments, air-filled nanostructures provide a refractive index gradient.

In another embodiment, a microstructured article comprising a plurality of discrete peak microstructures and at least a portion of the microstructures further comprise a plurality of nanostructures; wherein the microstructures have a complex shape.

The nanostructures are typically a plurality of substantially parallel linear grooves, as can be formed by a multi-tipped diamond wherein the tips have a pitch of less than 1 micron.

Also described is a method of making a microstructured article, such as a microstructured tool for making a (e.g. antireflective) matte film. The method comprises providing a diamond tool wherein at least a portion of the tool comprises a plurality of tips wherein the pitch of the tips is less than 1 micron; and cutting a substrate with the diamond tool wherein the diamond tool is moved in and out along a direction at a pitch (P₁), and the diamond tool has a maximum cutter width P₂ and P₂/P₁ is at least 2.

### BRIEF DESCRIPTION OF DRAWINGS

FIG. 1A-1C are schematic side-views of matte films comprising nanostructures;

FIG. 2A is a schematic side-view of microstructure depressions;

FIG. 2B is a schematic side-view of microstructure protrusions;

FIG. 3A is a schematic top-view of regularly arranged microstructures;

FIG. 3B is a schematic top-view of irregularly arranged microstructures;

FIG. 4 is a schematic side-view of a microstructure;

FIG. 5 is a schematic side-view of an optical film comprising a portion of microstructures comprising embedded matte particles;

FIG. 6 is a schematic side-view of a cutting tool system;

FIGS. 7A-7D are schematic side-views of various cutters;

FIG. 8 depicts a scanning election microscope image of a portion of a multi-tipped diamond tool suitable for making nanostructures;

FIG. 9 is a digital microscope image of an example of a microstructured surface at a magnification of 400× made from a microstructured tool prepared from a multi-tipped diamond tool;

FIG. 10 is a scanning electron microscope image of the nanostructures of the microstructured surface of FIG. 10;

FIG. 11 is a graph depicting the complement cumulative slope magnitude distribution for various matte microstructured surfaces;

FIG. 12 depicts the manner in which curvature is calculated.

FIG. 13A is a two-dimensional surface profile of an illustrative microstructured surface;

FIG. 13B is a three-dimensional surface profile of the microstructured surface of FIG. 13A;

FIG. 13C-13D are cross-sectional profiles of the microstructured surface of FIG. 13A alone the x- and y-directions respectively.

### DETAILED DESCRIPTION

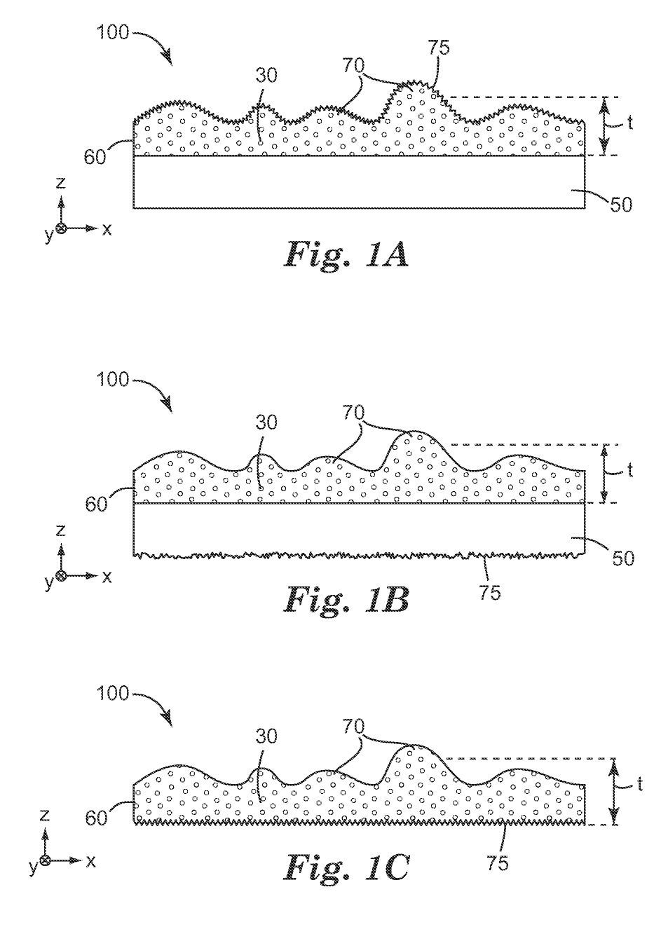

Presently described are microstructured articles, such as matte (i.e. antiglare) films, antireflective films, and microstructured tools. Also described is a method of making a microstructured article, such as a microstructured tool. With reference to FIGS. 1A-1C, the matte film 100 comprises a microstructured (e.g. viewing) surface layer 60 typically disposed on a light transmissive (e.g. film) substrate 50. The antireflective film of FIGS. 1A-1C further comprises a plurality of nanostructures 75. The nanostructures typically comprise air and function as a diffraction gradient. Alternatively, the plurality of nanostructures 75 may be filled with a material having a substantially different (e.g. lower) refractive index than the surrounding material. The difference in refractive index between the air of the nanostructures 75 and the surrounding material (e.g. of the microstructured viewing surface layer 60) is typically at least 0.10, or 0.15, or 0.2 or greater. Since the refractive index of air is 1.0, a variety of conventional polymerizable resin materials, such as hardcoat compositions optionally comprising (e.g. silica) nanoparticles or conventional film materials can be utilized to fabricate the nanostructured layer.

In favored embodiments, such as depicted in FIG. 1A, the microstructured surface further comprises nanostructures. In this embodiment, the nanostructures are present on the (e.g. exposed) surface of the microstructures. Thus, the nanostructures are sub-structures of the macro-scale microstructured surface. The nanostructures and microstructures are present on the same surface and have a common (e.g. air) interface. The (e.g. air-filled) nanostructures may be characterized are being embedded within the microstructured surface. Except for the portion of the nanostructure exposed to air, the shape of the nanostructure is generally defined by the adjacent microstructured material. As will subsequently be described, a microstructured (e.g. tool) surface further comprising nanostructures can be formed by use of a (e.g. single radius) multi-tipped diamond tool wherein the plurality of tips have a pitch of less than 1 micron. Such multi-tipped diamond may also be referred to as a “nanostructured diamond tool”. Hence, a microstructured surface wherein the microstructures further comprise nanostructures can be concurrently formed during diamond tooling fabrication of the microstructured tool.

The microstructured (e.g. optical) film article can then be fabricated using microreplication from the tool by casting and curing a hardenable (e.g. polymerizable) polymeric material in contact with the tool surface. Although the microstructured surface further comprising nanostructures typically comprises a light transmissive film substrate 50 adjacent an opposing surface as depicted in FIG. 1A, the microstructured surface can optionally be cast and cured onto a removeable release liner in which substrate 50 would not be present.

In other embodiments, the nanostructures are provided on a different surface than the microstructured surface. For example, the nanostructures can be provided on opposing (non-microstructured) surface, such as depicted in FIGS. 1B and 1C. In one embodiment, the matte (e.g. antireflective) film comprises nanostructures disposed on the (e.g. exposed) surface of an unstructured planar light transmissive substrate 50, such as depicted in FIG. 1B. Nanostructures, such as substantially parallel linear grooves, can be formed on a light transmissive (e.g. film) substrate 50 by subtractive processes such as by cutting the light transmissive (e.g. film) substrate 50 with a nanostructured diamond tool. Alternatively (not shown), such nanostructures can be formed by additive processed such as by microreplicating a thin layer of polymerizable resin onto the light transmissive (e.g. film) substrate 50 using a nanostructured tool (lacking the matte microstructures).

In yet another embodiment, a matte (e.g. antireflective) film can be prepared having matte microstructures on one surface and nanostructures on the opposing (non-microstructured) surface, wherein the film lacks a light transmissive substrate 50, as depicted in FIG. 1C. This embodiment can be formed by concurrent or sequential additive (e.g. microreplication) processes or a combination of additive and subtractive processes, as just described.

As depicted in FIGS. 1A-1C, the nanostructured surface is typically exposed to air, and thus does not form closed cells. Hence, the nanostructured surface is generally considered to be non-porous. In an alternative embodiment, a thin (e.g. low index) film layer may be applied to the nanostructured surface, encapsulating a mono-layer of air-filled nanostructures.

The nanostructures can have various shapes and sizes. In general, the nanostructures have a maximum dimension of less than the wavelength of light, i.e. less than 1 micron. In some embodiments, the nanostructures typically having a maximum dimension of no greater than 900 nm, or 800 nm, or 700 nm, or 600. The minimum dimension is typically at least 25 nm, 50 nm, or 100 nm. In favored embodiments, the nanostructures are of sufficient size and cover a sufficient surface area to provide the desired diffractive refractive index gradient. Hence, the presence of the nanostructures provides antireflective properties. For this embodiment, the nanostructures typically having a maximum dimension of no greater than 500 nm. In some favored embodiments, the nanostructures (e.g. optical the optical film) are substantially parallel linear grooves such as U-shaped or V-shaped grooves. In one embodiment, the substantially parallel linear grooves typically have a pitch of at least 100 nm and no greater than 500 nm. Further such grooves may have a depth of 100 nm to 200 nm.

The substrate 50, as well as the matte film, generally have a transmission of at least 85%, or 90%, and in some embodiments at least 91%, 92%, 93%, or greater. The transparent substrate may be a film. The film substrate thickness typically depends on the intended use. For most applications, the substrate thicknesses is preferably less than about 0.5 mm, and more preferably about 0.02 to about 0.2 mm. Alternatively, the transparent film substrate may be an optical (e.g. illuminated) display through which test, graphics, or other information may be displayed. The transparent substrate may comprise or consist of any of a wide variety of non-polymeric materials, such as glass, or various thermoplastic and crosslinked polymeric materials, such as polyethylene terephthalate (PET), (e.g. bisphenol A) polycarbonate, cellulose acetate, poly(methyl methacrylate), and polyolefins such as biaxially oriented polypropylene which are commonly used in various optical devices.

A durable matte (e.g. antireflective) film typically comprises a relatively thick microstructured matte (e.g. viewing) surface layer. The microstructured matte layer typically has an average thickness (“t”) of at least 0.5 microns, preferably at least 1 micron, and more preferably at least 2 or 3 microns. In some embodiments, the microstructured matte layer typically has a thickness of no greater than 15 microns and more typically no greater than 4 or 5 microns. However, when durability of the matte film is not required, the thickness of the microstructured matte layer can be thinner. In other embodiments, the thickness may be 200 microns or greater since the thickness of the layers need not be ¼ wave as in the case of conventional antireflective films comprising thin layers of differing refractive index materials. When the microstructured film lacks a support, such as substrate 50, the microstructured layer generally has a thickness of at least 25 microns or 50 microns. A wider variety of polymeric materials can be used to fabricate such thicker layers that may not be suitable for application at a thickness of ¼ wave.

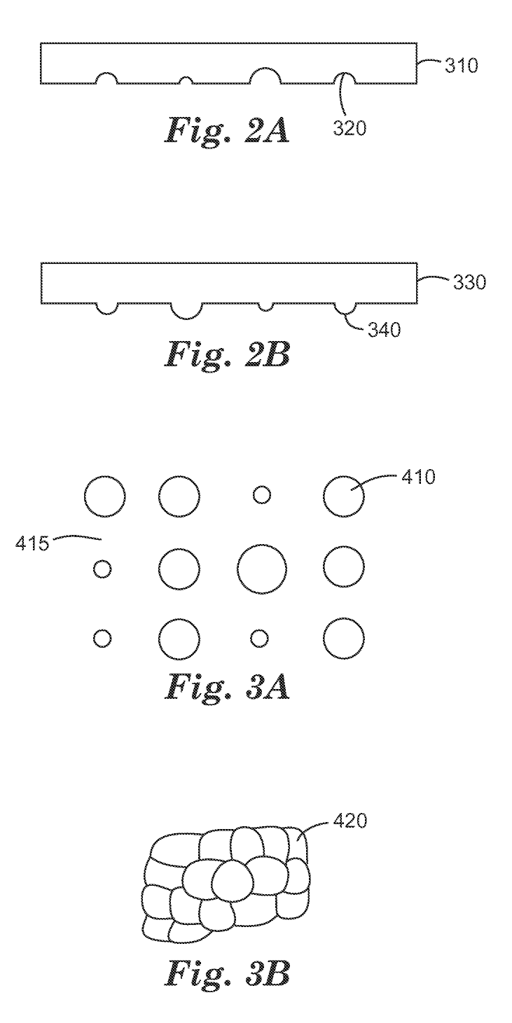

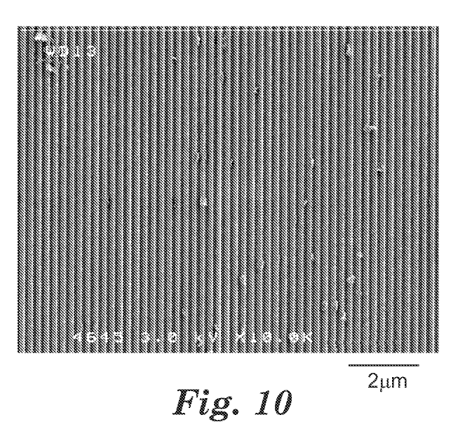

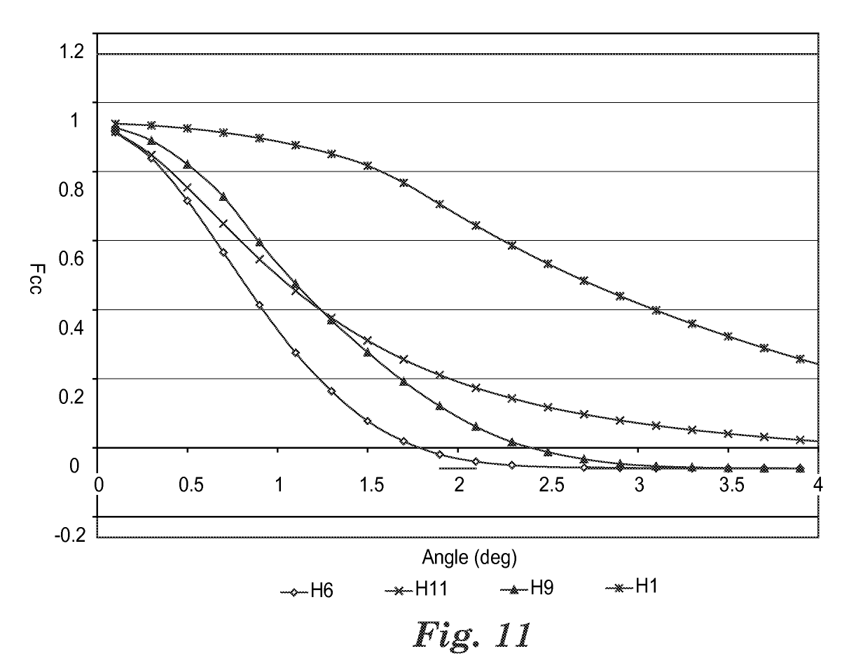

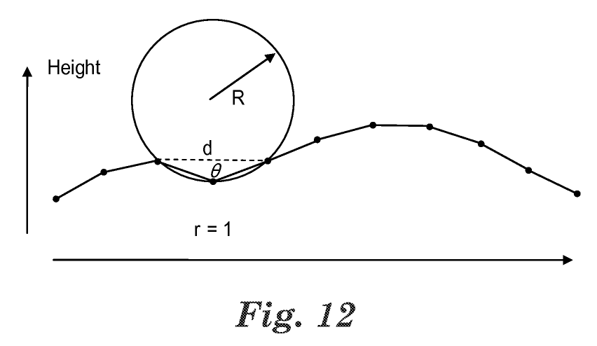

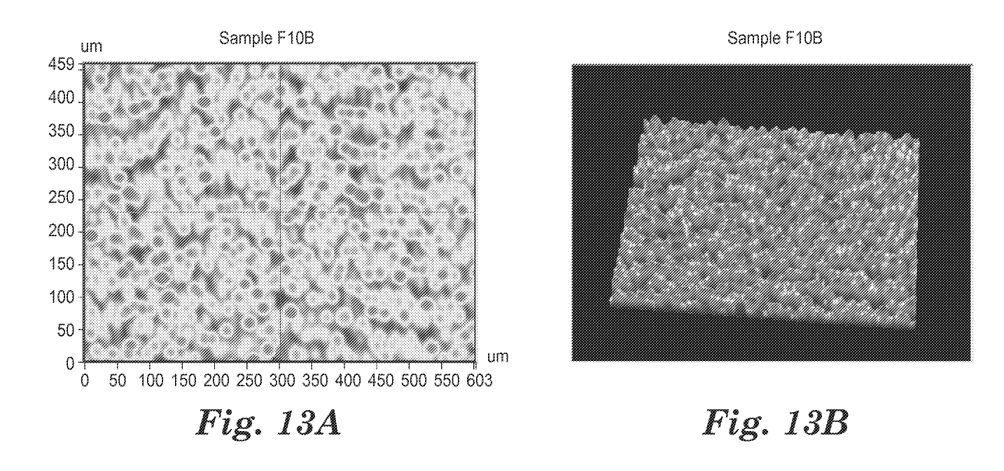

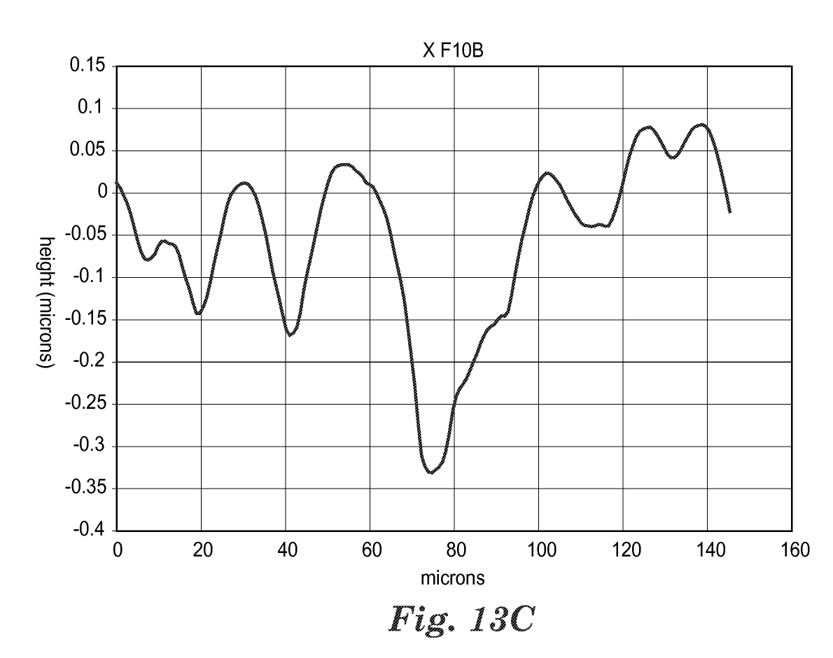

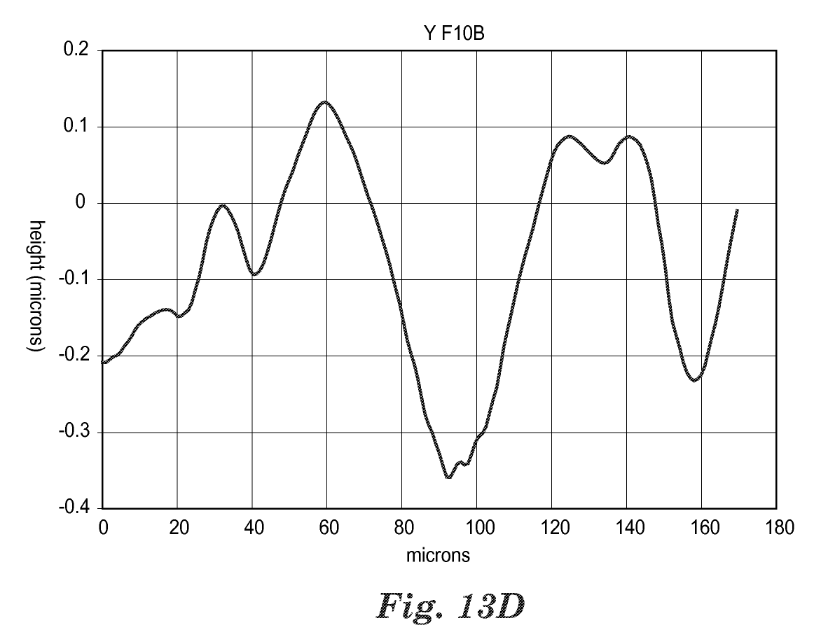

In some embodiments, the microstructures can be depressions. For example, FIG. 2A is a schematic side-view of microstructured (e.g. matte) layer 310 that includes depressed microstructures 320 or microstructure cavities. The tool surface from which the microstructured surface (e.g. of the optical film) is formed generally comprises a plurality of depressions. The microstructures of the matte film are typically protrusions. For example, FIG. 2B is a schematic side-view of a microstructured layer 330 including protruding microstructures 340. FIGS. 9D and 13A-13D depicts various microstructured surfaces comprising a plurality of discrete microstructure protrusions or peaks.

In some embodiments, the microstructures can form a regular pattern. For example, FIG. 3A is a schematic top-view of microstructures 410 that form a regular pattern in a major surface 415. Typically however, the microstructures form an irregular pattern. For example, FIG. 3B is a schematic top-view of microstructures 420 that form an irregular pattern. In some cases, microstructures can form a pseudo-random pattern that appears to be random. When the microstructured surface is prepared as a roll-good from a cylindrical tool, the microstructured roll-good has a repeating pattern corresponding to a revolution of the tool or a smaller dimension if the pattern repeats on the tool surface. If one were to inspect a microstructured article fabricated from such tool, wherein the article has a dimension smaller than the repeat pattern, the repetition of the pattern may not be evident and the microstructures would appear random.

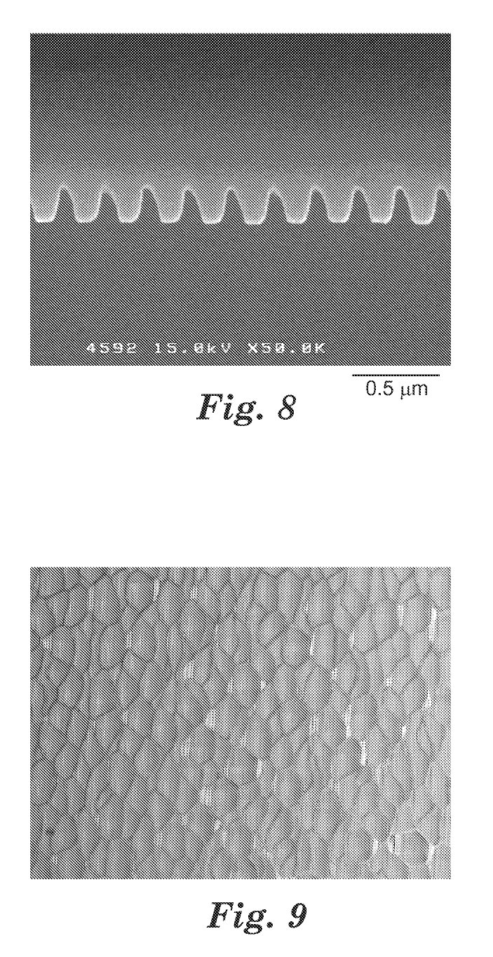

The nanostructures 75 can form a regular pattern, an irregular pattern or a pseudo-random pattern that appears to be random. In one favored embodiment, the nanostructures form a regular pattern. For example, the nanostructures (of the tool) may be formed by a nanostructured diamond tool, such as depicted in FIG. 8, wherein the nanostructures (e.g. grooves) have a common pitch. The nanostructures of the optical film thus formed by replication of the tool also have a constant pitch, forming a regular pattern. When the nanostructures are formed by a nanostructured diamond tool wherein the nanostructures have a constant height, the nanostructures (e.g. grooves) have a constant height relative to the microstructured surface. A nanostructured surface, wherein the nanostructures 75 form a regular pattern, are depicted in FIGS. 1A and 1C. Such nanostructures have a constant pitch and a constant height. Alternatively, a nanostructured surface wherein the nanostructures 75 form an irregular pattern is depicted in FIG. 1B. Such nanostructures have a randomly variable pitch and a randomly variable height.

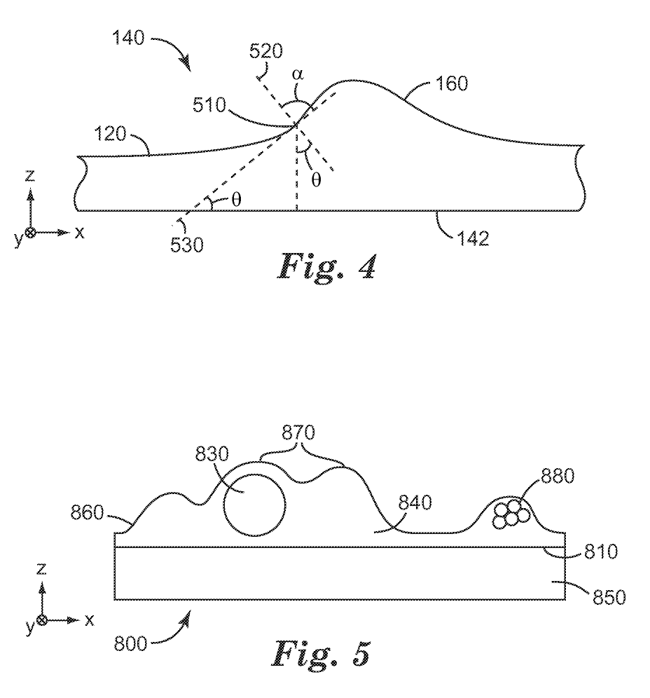

A (e.g. discrete) microstructure can be characterized by slope. FIG. 4 is a schematic side-view of a portion of a microstructured (e.g. matte) layer 140. In particular, FIG. 4 shows a microstructure 160 in major surface 120 and opposing (e.g. planar) major surface 142. Microstructure 160 has a slope distribution across the surface of the microstructure. For example, the microstructure has a slope θ at a location 510 where θ is the angle between normal line 520 which is perpendicular to the microstructure surface at location 510 (α=90 degrees) and a tangent line 530 which is tangent to the microstructure surface at the same location. Slope θ is also the angle between tangent line 530 and major surface 142 of the matte layer.

In general, the microstructures (e.g. of the matte or antireflective film) can typically have a height distribution. In some embodiments, the mean height (as measured according to the test method described in the examples) of microstructures is not greater than about 5 microns, or not greater than about 4 microns, or not greater than about 3 microns, or not greater than about 2 microns, or not greater than about 1 micron. The mean height is typically at least 0.1 or 0.2 microns.

In some embodiments, the microstructures are substantially free of (e.g. inorganic oxide or polystyrene) matte particles. However, even in the absence of matte particles, the microstructures 70 may optionally comprise (e.g. zirconia or silica) nanoparticles 30, as depicted in FIGS. 1A-1C.

The size of the nanoparticles is chosen to avoid significant visible light scattering. It may be desirable to employ a mixture of inorganic oxide particle types to optimize an optical or material property and to lower total composition cost. The surface modified colloidal nanoparticles can be inorganic oxide particles having a (e.g. unassociated) primary particle size or associated particle size of at least 1 nm or 5 nm. The primary or associated particle size is generally less than 100 nm, 75 nm, or 50 nm. Typically the primary or associated particle size is less than 40 nm, 30 nm, or 20 nm. It is preferred that the nanoparticles are unassociated. Their measurements can be based on transmission electron microscopy (TEM). Surface modified colloidal nanoparticles can be substantially fully condensed.

Due to the substantially smaller size of nanoparticles, such nanoparticles do not form a microstructure. Rather, the microstructures comprise a plurality of nanoparticles.

In other embodiments, a portion of the microstructures may comprise embedded matte particles.

Matte particles typically have an average size that is greater than about 0.25 microns (250 nanometers), or greater than about 0.5 microns, or greater than about 0.75 microns, or greater than about 1 micron, or greater than about 1.25 microns, or greater than about 1.5 microns, or greater than about 1.75 microns, or greater than about 2 microns. Smaller matte particles are typical for matte films that comprise a relatively thin microstructured layer. However, for embodiments wherein the microstructured layer is thicker, the matte particles may have an average size up to 5 microns or 10 microns. The concentration of matte particles may range from at least 1 or 2 wt-% to about 5, 6, 7, 8, 9, or 10 wt-% or greater.

FIG. 5 is a schematic side-view of an optical film 800 that includes a matte layer 860 disposed on a substrate 850. Matte layer 860 includes a first major surface 810 attached to substrate 850 and a plurality of matte particles 830 and/or matte particle agglomerates dispersed in a polymerized binder 840. A substantial portion, such as at least about 50%, or at least about 60%, or at least about 70%, or at least about 80%, or at least about 90%, of microstructures 870 lack the presence of a matte particle 830 or matte particle agglomerate 880. Thus such microstructures are free of (e.g. embedded) matte particles. It is surmised that the presence of (e.g. silica or CaCO₃) matte particles may provide improved durability even when the presence of such matte particles is insufficient to provide the desired antireflection, clarity, and haze properties as will subsequently be described. However, due to the relatively large size of matte particles, it can be difficult to maintain matte particles uniformly dispersed in a coating composition. This can cause variations in the concentration of matte particles applied (particularly in the case of web coating), which in turn causes variations in the matte properties.

For embodiments wherein at least a portion of the microstructures comprise an embedded matte particle or agglomerated matte particle, the average size of the matte particles is typically sufficiently less than the average size of microstructures (e.g. by at least a factor of about 2 or more) such that the matte particle is surrounded by the polymerizable resin composition of the microstructured layer as depicted in FIG. 5.

When the matte layer includes embedded matte particles, the matte layer typically has an average thickness “t” that is greater than the average size of the particles by at least about 0.5 microns, or at least about 1 micron, or at least about 1.5 microns, or at least about 2 microns, or at least about 2.5 microns, or at least about 3 microns.

The microstructured surface can be made using any suitable fabrication method. The microstructures are generally fabricated using microreplication from a tool by casting and curing a polymerizable resin composition in contact with a tool surface such as described in U.S. Pat. Nos. 5,175,030 (Lu et al.) and 5,183,597 (Lu). The tool may be fabricated using any available fabrication method, such as by using engraving or diamond turning. Exemplary diamond turning systems and methods can include and utilize a fast tool servo (FTS) as described in, for example, PCT Published Application No. WO 00/48037; U.S. Pat. No. 7,350,442; U.S. Pat. No. 7,328,638; and US 2009/0147361; each of which are incorporated by reference.

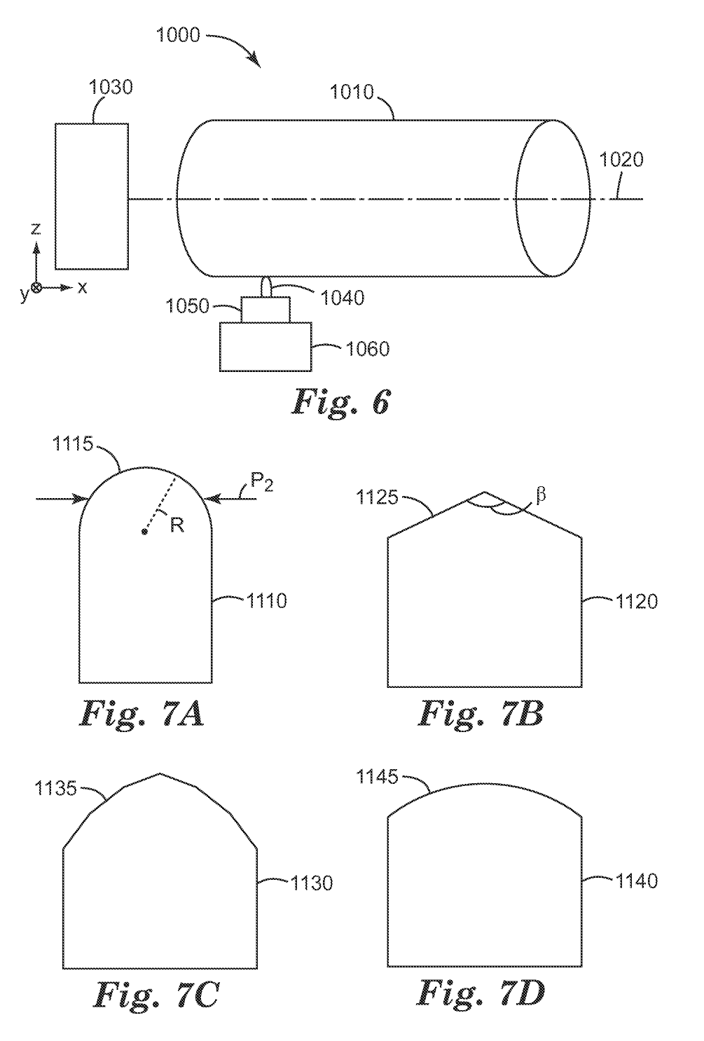

FIG. 6 is a schematic side-view of a cutting tool system 1000 that can be used to cut a tool which can be microreplicated to produce microstructures 160 and matte layer 140. Cutting tool system 1000 employs a thread cut lathe turning process and includes a roll 1010 that can rotate around and/or move along a central axis 1020 by a driver 1030, and a cutter 1040 for cutting the roll material. The cutter is mounted on a servo 1050 and can be moved into and/or along the roll along the x-direction by a driver 1060. In general, cutter 1040 can be mounted normal to the roll and central axis 1020 and is driven into the engraveable material of roll 1010 while the roll is rotating around the central axis. The cutter is then driven parallel to the central axis to produce a thread cut. Cutter 1040 can be simultaneously actuated at high frequencies and low displacements to produce features in the roll that when microreplicated result in microstructures 160.

Servo 1050 is a fast tool servo (FTS) and includes a solid state piezoelectric (PZT) device, often referred to as a PZT stack, which rapidly adjusts the position of cutter 1040. FTS 1050 allows for highly precise and high speed movement of cutter 1040 in the x-, y- and/or z-directions, or in an off-axis direction. Servo 1050 can be any high quality displacement servo capable of producing controlled movement with respect to a rest position. In some cases, servo 1050 can reliably and repeatably provide displacements in a range from 0 to about 20 microns with about 0.1 micron or better resolution.

Driver 1060 can move cutter 1040 along the x-direction parallel to central axis 1020. In some cases, the displacement resolution of driver 1060 is better than about 0.1 microns, or better than about 0.01 microns. Rotary movements produced by driver 1030 are synchronized with translational movements produced by driver 1060 to accurately control the resulting shapes of microstructures 160.

The engraveable material of roll 1010 can be any material that is capable of being engraved by cutter 1040. Exemplary roll materials include metals such as copper, various polymers, and various glass materials.

Cutter 1040 can be any type of cutter and can have any shape that may be desirable in an application. For example, FIG. 7A is a schematic side-view of a cutter 1110 that has an arc-shape cutting tip 1115 with a radius “R”. In some cases, the radius R of cutting tip 1115 is at least about 100 microns, or at least about 150 microns, or at least about 200 microns. In some embodiments, the radius R of the cutting tip is or at least about 300 microns, or at least about 400 microns, or at least about 500 microns, or at least about 1000 microns, or at least about 1500 microns, or at least about 2000 microns, or at least about 2500 microns, or at least about 3000 microns.

Alternatively, the microstructured surface of the tool can be formed using a cutter 1120 that has a V-shape cutting tip 1125, as depicted in FIG. 7B, a cutter 1130 that has a piece-wise linear cutting tip 1135, as depicted in FIG. 7C, or a cutter 1140 that has a curved cutting tip 1145, as depicted in 7D. In one embodiment, a V-shape cutting tip having an apex angle β of at least about 178 degrees or greater was employed.

The microstructured surface described herein wherein the microstructured surface further comprises nanostructures is preferably prepared by use of a multi-tipped diamond tool, such as described in U.S. Pat. No. 7,140,812 and US2008/0147361; incorporated herein by reference. The tips are adjacent to one another, and form a valley between the tips. Each tip of the diamond tool defines a separate cutting mechanism.

Focused ion beam milling processes can be used to form the tips and may also be used to form the valley of the diamond tool. For example, focused ion beam milling can be used to ensure that inner surfaces of the tips meet along a common axis to form a bottom of valley. Focused ion beam milling can be used to form features in the valley, such as a concave or convex arc ellipses, parabolas, mathematically defined surface patterns, or random or pseudo-random patterns. A wide variety of other shapes of valley could also be formed.

Precise creation of valley can be very important because the valley can define a protrusion to be created in a microreplication tool. For example, the valley may define a concave or convex arc having a radius defined relative to an external reference point, or may define an angle between the adjacent surfaces. Because the multiple tips are formed on a single diamond, alignment issues associated with the use of separate diamonds in a single tool can be avoided. Hence, these multi-tip diamonds are amenable to providing substantially parallel nanostructures concurrently with forming larger microstructures (e.g. of the matte surface).

As illustrated in FIG. 8, a scanning electron micrograph of a portion of a diamond tool, the diamond tip comprises a plurality of tips. In order to form nanostructures, the pitch between tips and/or valleys of the tool is less than the wavelength of light, i.e. less than 1 micron. The pitch corresponds to the pitch (e.g. nanostructure width) of the substantially parallel linear nanostructures present on the microstructured surface of the tool and microstructured surface (e.g. of the optical films) formed from such tool. In some embodiments, the average pitch is no greater than 900 nm, or 800 nm, or 700 nm, or 500 nm. The pitch is typically at least 25 nm, 50 nm, or 100 nm. In the case of antireflective films, the nanostructures are of sufficient size and cover sufficient surface area to provide the desired diffractive index gradient. Although the diamond tool of FIG. 8 comprises a plurality of tips wherein the pitch is nominally the same (i.e. constant pitch), the pitch between adjacent microstructures could alternatively be varied. If the variation is random, such nanostructured surface would form an irregular pattern, such as depicted by the nanostructured surface of FIG. 1B.

Referring back to FIG. 6, the rotation of roll 1010 along central axis 1020 and the movement of (e.g. multi-tipped diamond tool) cutter 1040 along the x-direction while cutting the roll material define a thread path around the roll that has a pitch P₁ along the central axis. As the cutter moves along a direction normal to the roll surface to cut the roll material, the width of the material cut by the cutter changes as the cutter moves or plunges in and out. Referring to, for example FIG. 7A, the maximum penetration depth by the cutter corresponds to a maximum width P₂ cut by the cutter. When P₂/P₁ is less than 1, the maximum width P₂ cut by the cutter is no greater than the pitch P₁. Hence, a first thread path around the roll does not overlap with a second adjacent thread path around the roll. However, when P₂/P₁ is greater than 1, the thread paths overlap. The microstructures do not have a shape that corresponds directly to the shape of the diamond tool as would be the case when a single V-shaped diamond tool is used to cut a V-shaped groove. Rather the microstructures are formed by the movement of the cutter moving or plunging in and out in combination with the overlapping cuts (i.e. overlapping thread paths). Hence, a single microstructure has faces formed by two or more overlapping cuts. In some embodiments, P₂/P₁ is at least 1.5 or 2. A P₂/P₁ ratio of at least 2.0 is amenable to the formation of discrete (e.g. peak) microstructures. The P₂/P₁ ratio may range up to 15. In one favored embodiment for the formation of a matte microstructured surface, the ratio P₂/P₁ is in a ranges from about 2 to about 4.

The multi-tipped diamond cutter is aligned such that the substantially parallel linear grooves of the nanostructured tool are substantially parallel to the edge of the roll (i.e. the y-axis in FIG. 6). Further, the substantially parallel linear grooves of the nanostructured tool are substantially orthogonal to the x-axis (i.e. crossweb). Hence, the microstructured tool and article replicated from such tool generally comprise a plurality of nanostructures that are substantially parallel to the downweb direction and substantially orthogonal to the crossweb direction of the microstructured article. If an overlapping cut is made such that the nanostructured grooves of the overlapping cut is coincident with the nanostructured grooves of a previous (e.g. adjacent) cut, the nanostructures may be continuous. If the overlapping cuts are made such that the nanostructured grooves are not coincident, a discontinuity is present at the intersection of the overlapping cuts. A portion of the nanostructures of each microstructure are typically continuous for a (e.g. downweb) dimension (e.g. length or width) of a microstructure. Further, a portion of the nanostructures are also typically continuous with other (e.g. downweb) microstructures. Hence, the length of a continuous nanostructured groove is typically on the order of at least 5 or 10 microns, such as depicted in the scanning electron micrograph of a portion of a nanostructured surface, as depicted in FIG. 10.

Overlapping cuts generally give rise to microstructures having a complex shape. As used herein, “complex shape” refers to a single microstructures having adjacent surface portions comprising a discontinuity in either the first or second derivative at the line of adjacency. When a single microstructures comprises adjacent surface portions having different slopes, such surface portions would have a different first derivative at the line of adjacency. Similarly, adjacent planar and/or curved surface portions may have a constant first derivative or slope at the line of adjacency but a discontinuity in the second derivative.

A microstructured layer was made by microreplicating a patterned tool to make antireflective matte layers. Since the microstructured surface of the matte layer was a precise (e.g. positive) replication of the tool surface, the forthcoming description of the microstructured layer is also a description of the inverse (i.e. negative replication) of the tool surface.

Representative portions of the microstructured surface of the fabricated samples, having an area ranging from about 200 microns by 250 microns to an area of about 500 microns by 600 microns, were characterized using phase shift interferometry according to the test method described in the examples. Atomic force microscopy (AFM) or confocal microscopy can also be used to characterize the microstructured surface.

An example of surface profiles of an illustrative microstructured layer (e.g. further comprising nanostructures) is depicted in FIG. 9 and FIGS. 13A-13D. The microstructured surface generally comprises a variety of differently shaped microstructures having different sizes and a distribution of slope. The slope of at least 50% of the microstructures is typically less than 10 degrees. These surface profiles are representative of a microstructured surface comprising discrete microstructures wherein the microstructures form an irregular or pseudo-random pattern. As is particularly evident in FIGS. 13C and 13D the discrete peak microstructures have a complex shape. Further, the discrete peak microstructures are defined by a valley surrounding each peak. The lowest portions of the valley are typically not in a common plane.

The F_{cc}(θ) complement cumulative slope magnitude distribution of the slope distribution is defined by the following equation

$${F}_{CC} ( θ ) = \frac{{\sum }_{q = θ}^{∞} {N}_{G} ( q )}{{\sum }_{q = 0}^{∞} {N}_{G} ( q )} .$$

F_{cc} at a particular angle (θ) is the fraction of the slopes that are greater than or equal to 0.

The microstructured surface further comprising nanostructures may have the same (e.g. matte surface) characteristics as described in PCT publication no. WO2010/141345 and U.S. Patent Applications 61/332,231 filed May 7, 2010 and 61/349,318, filed May 28, 2010; each of which are incorporated herein by reference. At least 90% or greater of the microstructures have a F_{cc}(θ) complement cumulative slope magnitude of at least 0.1 degrees or greater. Further, at least 75% of the microstructures have a slope magnitude of at least 0.3 degrees.

The preferred microstructured surface, having high clarity and low haze, suitable for use as a front (e.g. viewing) surface matte layer have a F_{cc}(θ) complement cumulative slope magnitude such that at least 25% or 30% or 35% or 40% and in some embodiments at least 45% or 50% or 55% or 60% or 65% or 70% or 75% of the microstructures have a slope magnitude of at least 0.7 degrees. Thus, at least 25% or 30% or 35% or 40% or 45% or 50% or 55% or 60% or 65% or 70% have a slope magnitude less than 0.7 degrees.

Alternatively or in addition thereto, the preferred microstructured surface can be-characterized by at least 25% of the microstructures having a slope magnitude of less than 1.3 degrees. In some embodiments, at least 30%, or 35%, or 40%, or 45% of the microstructures have a slope magnitude of at least 1.3 degrees. Hence, 55% or 60% or 65% of the microstructures have a slope magnitude less than 1.3 degrees. In other embodiments, at least 5% or 10% or 15% or 20% of the microstructures have a slope magnitude of at least 1.3 degrees. Hence, 80% or 85% or 90% or 95% of the microstructures have a slope magnitude less than 1.3 degrees.

Alternatively or in addition thereto, the matte microstructured surface can be characterized by less than 20% or 15% or 10% of the microstructures having a slope magnitude of 4.1 degrees or greater. Thus, 80% or 85% or 90% have a slope magnitude less than 4.1 degrees. In one embodiment, 5 to 10% of the microstructures have a slope magnitude of 4.1 degrees or greater. In some embodiments, less than 5% or 4% or 3% or 2% or 1% of the microstructures have a slope magnitude of 4.1 degrees or greater.

The microstructured surface comprises a plurality of discrete peak microstructures, as described in previously cited PCT publication no. WO2010/141345 and U.S. Patent Applications 61/332,231 filed May 7, 2010 and 61/349,318, filed May 28, 2010.

Such dimensional characteristics have been found to relate to “sparkle”, which is a visual degradation of an image displayed through a matte surface due to interaction of the matte surface with the pixels of an LCD. The appearance of sparkle can be described as a plurality of bright spots of a specific color that superimposes “graininess” on an LCD image detracting from the clarity of the transmitted image. The level, or amount, of sparkle depends on the relative size difference between the microreplicated structures and the pixels of the LCD (i.e. the amount of sparkle is display dependent). In general, the microreplicated structures need to be much smaller than LCD pixel size to eliminate sparkle. The amount of sparkle is evaluated by visual comparison with a set of physical acceptance standards (samples with different levels of sparkle) on a LCD display available under the trade designation “Apple iPod Touch” (having a pixel pitch of about 159 μm as measured with a microscope) in the white state. The scale ranges from 1 to 4, with 1 being the lowest amount of sparkle and 4 being the highest.

The microstructured surfaces having low sparkle can be characterized as having a mean ECD of at least 5 microns and typically of at least 10 microns. Further, the microstructured surface typically has a mean ECD (i.e. peak) of less than 30 microns or less than 25 microns. The peaks of the low sparkle microstructured surfaces have a mean length of greater than 5 microns and typically greater than 10 microns. The mean width of the peaks of the microstructured surfaces is also at least 5 microns. The peaks of the low sparkle microstructured surfaces have a mean length of no greater than about 20 microns, and in some embodiments no greater than 10 or 15 microns. The ratio of width to length (i.e. W/L) is typically at least 1.0, or 0.9, or 0.8. In some embodiments, the W/L is at least 0.6. In another embodiment, the W/L is less than 0.5 or 0.4 and is typically at least 0.1 or 0.15. The nearest neighbor (i.e. NN) is typically at least 10 or 15 microns and no greater than 100 microns. In some embodiments, the NN ranges from 15 microns to about 20 microns, or 25 microns. The higher sparkle embodiments typically have a NN of at least about 30 or 40 microns.

The plurality of peaks of the microstructured surface can also be characterized with respect to mean height, average roughness (Ra), and average maximum surface height (Rz).

The average surface roughness (i.e. Ra) is typically less than 0.20 microns. The favored embodiments having high clarity in combination with sufficient haze exhibit a Ra of less no greater than 0.18 or 0.17 or 0.16 or 0.15 microns. In some embodiments, the Ra is less than 0.14, or 0.13, or 0.12, or 0.11, or 0.10 microns. The Ra is typically at least 0.04 or 0.05 microns.

The average maximum surface height (i.e. Rz) is typically less than 3 microns or less than 2.5 microns. The favored embodiments having high clarity in combination with sufficient haze exhibit an Rz of less no greater than 1.20 microns. In some embodiments, the Rz is less than 1.10 or 1.00 or 0.90, or 0.80 microns. The Rz is typically at least 0.40 or 0.50 microns.

With regard to the exemplified microstructured layer and favored matte films, the microstructures cover substantially the entire surface. However, without intending to be bound by theory it is believed that the microstructures having slope magnitudes of at least 0.7 degrees provide the desired matte properties. Hence, it is surmised that the microstructures having a slope magnitudes of at least 0.7 degrees may cover at least about 25%, or at least about 30%, or at least about 35%, or at least about 40%, or at least about 45%, or at least about 50%, or at least about 55%, or at least about 60%, or at least about 65%, or at least about 70%, of the major surface, yet still provide the desired high clarity and low haze.

With regard to the exemplified microstructured layer and favored antireflective films, the nanostructures cover substantially the entire surface. However, the nanostructures may cover less than substantially the entire surface yet still provide adequate antireflective properties. Further, in the absences of sufficient nanostructures to render the film antireflective, the film exhibits adequate matte properties. In some embodiments, the nanostructures cover at least about 25%, or at least about 30%, or at least about 35%, or at least about 40%, or at least about 45%, or at least about 50%, or at least about 55%, or at least about 60%, or at least about 65%, or at least about 70%, of the major surface.

The optical clarity, as measured using a Haze-Gard Plus haze meter (available from BYK-Gardiner, Silver Springs, Md.), of the microstructured surface or optical film is generally at least about 40%, 45%, or 50%. In some embodiments, the optical clarity is at least 60% or 65% or 70% or 75% or 80%. In some embodiments, the clarity is no greater than 90%, or 89%, or 88%, or 87%, or 86%, or 85%.

Optical haze is typically defined as the ratio of the transmitted light that deviates from the normal direction by more than 2.5 degrees to the total transmitted light. The optical haze, as also measured using a Haze-Gard Plus haze meter according to the procedure described in ASTM D1003, of the microstructured surface or optical film is generally less than 20%, preferably less than 15%, and more preferably less than 10%. In favored embodiments, the optical haze ranges from about 0.5%, or 0.75%, or 1% to about 3%, 4%, or 5%.

Preferred antireflective matte films described herein exhibit an average photopic reflectance (i.e. Rphot) of less than 2%, or less than 1.5%, or less than 1% at 550 nm as measured with a spectrophotometer as just described.

The microstructured layer of the matte film typically comprises a polymeric material such as the reaction product of a polymerizable resin. The polymerizable resin preferably comprises surface modified nanoparticles. A variety of free-radically polymerizable monomers, oligomers, polymers, and mixtures thereof can be employed in the organic material of the microstructured layer.

In some embodiments, the microstructured layer of the matte film has a high refractive index, i.e. of at least 1.60 or greater. In some embodiments, the refractive index is at least 1.62 or at least 1.63 or at least 1.64 or at least 1.65. When the microstructured layer has a high index, such layer may be prepared from polymerizable compositions having a high refractive index such as those comprising aromatic monomers optionally comprising high refractive index nanoparticles such as (e.g. surface modified) zirconia, as described in previously cited U.S. Patent Application 61/332,231 filed May 7, 2010 and 61/349,318, filed May 28, 2010.

However, when the antireflective film further comprises air-filled nanostructures as described herein, the material of the microstructured layer can have a substantially lower refractive index and thus utilize a variety of more conventional low cost materials.

In favored embodiments, the microstructured layer of the (e.g. antireflective) film has a refractive index of less than 1.60. For example, the microstructured layer may have refractive index ranging from about 1.40 to about 1.60. In some embodiments, the refractive index of the microstructured layer is at least about 1.47, 1.48, or 1.49.

The microstructured layer having a refractive index of less than 1.60 typically comprises the reaction product of a polymerizable composition comprising one or more free-radically polymerizable materials and optionally surface modified inorganic nanoparticles, typically having a low refractive index (e.g. less than 1.50).

Various free-radically polymerizable monomers and oligomers such as various (meth)acrylate monomers have been described for use in conventional polymerizable compositions including for example (a) di(meth)acryl containing compounds such as 1,3-butylene glycol diacrylate, 1,4-butanediol diacrylate, 1,6-hexanediol diacrylate, 1,6-hexanediol monoacrylate monomethacrylate, ethylene glycol diacrylate, alkoxylated aliphatic diacrylate, alkoxylated cyclohexane dimethanol diacrylate, alkoxylated hexanediol diacrylate, alkoxylated neopentyl glycol diacrylate, caprolactone modified neopentylglycol hydroxypivalate diacrylate, caprolactone modified neopentylglycol hydroxypivalate diacrylate, cyclohexanedimethanol diacrylate, diethylene glycol diacrylate, dipropylene glycol diacrylate, ethoxylated (10) bisphenol A diacrylate, ethoxylated (3) bisphenol A diacrylate, ethoxylated (30) bisphenol A diacrylate, ethoxylated (4) bisphenol A diacrylate, hydroxypivalaldehyde modified trimethylolpropane diacrylate, neopentyl glycol diacrylate, polyethylene glycol (200) diacrylate, polyethylene glycol (400) diacrylate, polyethylene glycol (600) diacrylate, propoxylated neopentyl glycol diacrylate, tetraethylene glycol diacrylate, tricyclodecanedimethanol diacrylate, triethylene glycol diacrylate, tripropylene glycol diacrylate; (b) tri(meth)acryl containing compounds such as glycerol triacrylate, trimethylolpropane triacrylate, ethoxylated triacrylates (e.g., ethoxylated (3) trimethylolpropane triacrylate, ethoxylated (6) trimethylolpropane triacrylate, ethoxylated (9) trimethylolpropane triacrylate, ethoxylated (20) trimethylolpropane triacrylate), propoxylated triacrylates (e.g., propoxylated (3) glyceryl triacrylate, propoxylated (5.5) glyceryl triacrylate, propoxylated (3) trimethylolpropane triacrylate, propoxylated (6) trimethylolpropane triacrylate), trimethylolpropane triacrylate, tris(2-hydroxyethyl)isocyanurate triacrylate; (c) higher functionality (meth)acryl containing compounds such as ditrimethylolpropane tetraacrylate, dipentaerythritol pentaacrylate, ethoxylated (4) pentaerythritol tetraacrylate, caprolactone modified dipentaerythritol hexaacrylate; (d) oligomeric (meth)acryl compounds such as, for example, urethane acrylates, polyester acrylates, epoxy acrylates; polyacrylamide analogues of the foregoing; and combinations thereof. Such compounds are widely available from vendors such as, for example, Sartomer Company of Exton, Pa.; UCB Chemicals Corporation of Smyrna, Ga.; and Aldrich Chemical Company of Milwaukee, Wis. Additional useful (meth)acrylate materials include hydantoin moiety-containing poly(meth)acrylates, for example, as described in U.S. Pat. No. 4,262,072 (Wendling et al.). Additional useful materials include acrylate functional urethane resins (i.e. urethane (meth)acrylates), such as those sold by Sartomer, Cognis, Bayer Material Science, among others.

In some embodiments, the microstructured layer is prepared from a (e.g. polymerizable) resin composition that is free of (e.g. silica) nanoparticles. For example, the microreplicated layer may be prepared from a composition comprising an aliphatic urethane acrylate (CN9893) and hexanediol acrylate (SR238).

In other embodiments, the microstructured layer is prepared from a (e.g. polymerizable) resin composition comprising (e.g. silica) nanoparticles.

Silicas for use in the moderate refractive index composition are commercially available from Nalco Chemical Co., Naperville, Ill. under the trade designation “Nalco Collodial Silicas” such as products 1040, 1042, 1050, 1060, 2327 and 2329. Suitable fumed silicas include for example, products commercially available from DeGussa AG, (Hanau, Germany) under the trade designation, “Aerosil series OX-50”, as well as product numbers -130, -150, and -200. Fumed silicas are also commercially available from Cabot Corp., Tuscola, Ill., under the trade designations CAB-O-SPERSE 2095″, “CAB-O-SPERSE A105”, and “CAB-O-SIL M5”.

The concentration of (e.g. inorganic) nanoparticles in the microstructured matte layer is typically at least 25 wt-% or 30 wt-%. The moderate refractive index layer typically comprises no greater than 50 wt-% or 40 wt-% inorganic oxide nanoparticles. The concentration of inorganic nanoparticles in the high refractive index layer is typically at least 40 wt-% and no greater than about 60 wt-% or 70 wt-%.

The inorganic nanoparticles are preferably treated with a surface treatment agent. Silanes are preferred for silica and other for siliceous fillers. Silanes and carboxylic acids are preferred for metal oxides such as zirconia. Various surface treatments are known, some of which are described in US2007/0286994.

In one embodiment, the microreplicated layer is prepared from a composition comprising about a 1 to 1 ratio of a crosslinking monomer (SR444) comprising at least three (meth)acrylate groups and surface modified silica.

The polymerizable compositions of the microstructured layer typically comprise at least 5 wt-% or 10 wt-% of crosslinker (i.e. a monomer having at least three (meth)acrylate groups). The concentration of crosslinker in the low refractive index composition is generally no greater than about 30 wt-%, or 25 wt-%, or 20 wt-%. The concentration of crosslinker in the high refractive index composition is generally no greater than about 15 wt-%.

Suitable crosslinker monomers include for example trimethylolpropane triacrylate (commercially available from Sartomer Company, Exton, Pa. under the trade designation “SR351”), ethoxylated trimethylolpropane triacrylate (commercially available from Sartomer Company, Exton, Pa. under the trade designation “SR454”), pentaerythritol tetraacrylate, pentaerythritol triacrylate (commercially available from Sartomer under the trade designation “SR444”), dipentaerythritol pentaacrylate (commercially available from Sartomer under the trade designation “SR399”), ethoxylated pentaerythritol tetraacrylate, ethoxylated pentaerythritol triacrylate (from Sartomer under the trade designation “SR494”) dipentaerythritol hexaacrylate, and tris(2-hydroxy ethyl)isocyanurate triacrylate (from Sartomer under the trade designation “SR368”). In some aspects, a hydantoin moiety-containing multi-(meth)acrylates compound, such as described in U.S. Pat. No. 4,262,072 (Wendling et al.) is employed.

The method of forming a matte coating on an optical display or a film may include providing a light transmissible substrate layer; and providing a microstructured layer on the substrate layer. When the microstructured layer is prepared from a microstructured tool comprising a plurality of microstructure depressions wherein the depressions further comprise a plurality of (substantially parallel linear) nanostructures, the microstructures and nanostructures are concurrently formed during replication of the tool surface.

The microstructured layer may be cured for example by exposure to ultraviolet radiation using an H-bulb or other lamp at a desired wavelength, preferably in an inert atmosphere (less than 50 parts per million oxygen). The reaction mechanism causes the free-radically polymerizable materials to crosslink. The cured microstructured layer may be dried in an oven to remove photoinitiator by-products or trace amount of solvent if present. Alternatively, a polymerizable composition comprising higher amounts of solvents can be pumped onto a web, dried, and then microreplicated and cured.

Although it is usually convenient for the substrate to be in the form of a roll of continuous web, the coatings may be applied to individual sheets.

The substrate can be treated to improve adhesion between the substrate and the adjacent layer, e.g., chemical treatment, corona treatment such as air or nitrogen corona, plasma, flame, or actinic radiation. If desired, an optional tie layer or primer can be applied to the substrate and/or hardcoat layer to increase the interlayer adhesion. Alternatively or in addition thereto the primer may be applied to reduce interference fringing, or to provide antistatic properties.

Various permanent and removable grade adhesive compositions may be provided on the opposite side of the film substrate. For embodiments that employ pressure sensitive adhesive, the antireflective film article typically include a removable release liner. During application to a display surface, the release liner is removed so the antireflective film article can be adhered to the display surface.

### EXAMPLES

### Microstructured Surface Characterization

The following method was used to identify and characterize peak regions and of interest in height profiles that were obtained by phase shifting interferometry (PSI) by use of a Wyko Surface Profiler with a 10× objective, over an area ranging from about 200 microns by 250 microns to area of about 500 microns by 600 microns. The method uses thresholding on the curvature and an iterative algorithm to optimize the selection. Using curvature instead of a simple height threshold helps pick out relevant peaks that reside in valleys. In certain cases, it also helps avoid the selection of a single continuous network.

Prior to analyzing the height profiles, a median filter is used to reduce the noise. Then for each point in the height profile, the curvature parallel to the direction of the steepest slope (along the gradient vector) was calculated. The curvature perpendicular to this direction was also calculated. The curvature was calculated using three points and is described in the following section. Peak regions are identified by identifying areas that have positive curvature in at least one of these two directions. The curvature in the other direction cannot be too negative. To accomplish this, a binary image was created by using thresholding on these two curvatures. Some standard image processing functions were applied to the binary image to clean it up. In addition, peak regions that are too shallow are removed.

The size of the median filter and the distance between the points used for the curvature calculations are important. If they are too small, the main peaks may break up into smaller regions due to imperfections on the peak. If they are too large, relevant peaks may not be identified. These sizes were set to scale with the size of the peak regions or the width of the valley region between the peaks, whichever is smaller. However, the region sizes depend on the size of the median filter and the distance between the points for the curvature calculations. Therefore, an iterative process was used to identify a spacing that satisfies some preset conditions that result in good peak identification.

Valleys can be identified in the same manner by first inverting the image to convert valleys into peaks.

### Slope and Curvature Analysis

Surface profile data gives height of the surface as a function of x and y positions. We will represent this data as a function H(x,y). The x direction of the image is the horizontal direction of the image. The y direction of the image is the vertical direction of the image.

MATLAB was used to calculate the following:

1. gradient vector

$$\begin{matrix}∇ H ( x , y ) = ( \frac{\partial H ( x , y )}{\partial x} , \frac{\partial H ( x , y )}{\partial y} ) \\ = ( \begin{matrix}\frac{H ( x + Δ x , y ) - H ( x - Δ x , y )}{2 Δ x} , \\ \frac{H ( x , y + Δ y ) - H ( x , y - Δ y )}{2 Δ y}\end{matrix} )\end{matrix}$$

2. slope (in degrees) distribution—N_{G}(O)

$$\begin{matrix}θ = arctan ( \vert ∇ H ( x , y ) \vert ) \\ = arctan ( \sqrt{\begin{matrix}{( \frac{H ( x + Δ x , y ) - H ( x - Δ x , y )}{2 Δ x} )}^{2} + \\ {( \frac{H ( x , y + Δ y ) - H ( x , y - Δ y )}{2 Δ y} )}^{2}\end{matrix}} )\end{matrix}$$

3. F_{cc}(θ)—complement cumulative distribution of the slope distribution

$${F}_{CC} ( θ ) = \frac{{\sum }_{q = θ}^{∞} {N}_{G} ( q )}{{\sum }_{q = 0}^{∞} {N}_{G} ( q )}$$

F_{cc}(θ) is the complement of the cumulative slope distribution and gives the fraction of slopes that are greater than or equal to θ.

4. g-curvature, curvature in the direction of the gradient vector (inverse microns)

5. t-curvature, curvature in the direction transverse to the gradient vector (increase microns)

### Curvature

As depicted in FIG. 13, the curvature at a point is calculated using the two points used for the slope calculation and the center point. For this analysis, the curvature is defined as one divided by the radius of the circle that inscribes the triangle formed by these three points.

curvature=±1/R=±2*sin(θ)/d

where θ is the angle opposite the hypotenuse, and d is the length of the hypotenuse of the triangle. The curvature is defined to be negative if the curve is concave up and positive if concave down.

The curvature is measured along the x direction (i.e. x-curvature), along the y direction (i.e. y-curvature), along the gradient vector direction (i.e. g-curvature) and along the direction transverse to the gradient vector (i.e. t-curvature). Interpolation is used to obtain the two end points.

### Peak Sizing

The curvature profile is used to obtain size statistics for peaks on the surface of samples. Thresholding of the curvature profile is used to generate a binary image that is used to identify peaks. Using MATLAB, the following thresholding was applied at each pixel to generate the binary images for peak identification:

max(g-curvature,t-curvature)>c0max

min(g-curvature,t-curvature)>c0min

where c0max and c0min are curvature cutoff values. Typically, c0max and c0min were assigned as follows:

c0max=2 sin(q₀)N₀/fov (q₀ and N₀ are fixed parameters)

c0min=−c0max

q₀ should be an estimate of the smallest slope (in degrees) that is of significance. N₀ should be an estimate of the least number of peak regions that is desirable to have across the longest dimension of the field of view. fov is the length of the longest dimension of the field of view.

MATLAB with the image processing tool box was used to analyze the height profiles and generate the peak statistics. The following sequence gives an outline of the steps in the MATLAB code used to characterize peak regions.
1. If number of pixels>=1001*1001 then reduce number of pixels
   calculate nskip=fix(na*nb/1001/1001)+1
      original image has size na×nb pixels
   if nskip>1 then carry out (2*fix(nskip/2)+1)×(2*fix(nskip/2)+1) median averaging
      fix is a function that rounds down to the nearest integer.
   create new image keeping every nskip pixel in each direction (e.g. keep rows and columns 1, 4, 8, 11 . . . if nskip=3)
2. r=round(Δx/pix)
   Δx is the step size that will be used in the slope calculation
   pix is the pixel size.
   r is Δx rounded to the nearest whole numbers of pixels
   an initial value for Δx is chosen by the user prior to running the program or is chosen to be equal to ffov*fov.
      ffov is a parameter chosen by the user prior to running the program
3. Perform median averaging with window size of round(f_{MX}*r)×round(f_{MY}*r) pixels.
   If the regions are oriented then median averaging is done with a window with an aspect ratio (W/L) close to that of a typical region as defined below. The window aspect ratio is not allowed to go below the preset value rm aspect min.
      Note that if the regions are oriented, the height profiling should be performed with the sample aligned such that this orientation is along the x or y axis.
   For this analysis, the regions are considered oriented if
      mean orientation angle of the regions (weighted by region area) is less then 15 degrees or greater then 75 degrees.
         1. orientation angle is defined as the angle that the major axis of the ellipse associated with the region makes with the y-axis.
      standard deviation of this orientation angle is less than 25 degrees
      coverage is greater then 10%
   If this is the first round or the regions are not oriented then
      f_{MX} and f_{MY} is set equal to f_{M}
   If the orientation is along the y-axis
      f_{MX}=round(f_{M}*r*sqrt(aspect));
      f_{MY}=round(f_{M}*r/sqrt(aspect));
   If the orientation is along the x-axis
      f_{MX}=round(f_{M}*r/sqrt(aspect));
      f_{MY}=round(f_{M}*r*sqrt(aspect));
   aspect=the mean aspect ratio weighted by region area
      if it is less than rm_aspect_min, it is set equal to rm_aspect_min.
   f_{M} is a fixed parameter chosen before running the program.
4. Remove tilt.
   effectively makes the average slope across the entire profile in all directions equal to zero
5. Calculate slope profiles as previously described.
6. Calculate curvature profiles in the direction parallel to the gradient vector (g-curvature) and in the direction transverse to the gradient vector (t-curvature).
7. Create a binary image using the curvature thresholding described above.
8. Erode the binary image.
   the number of times the image is eroded is set equal to round(r*f_{E})
   f_{E} is a fixed parameter (typically ≦1), chosen before initiating the program
   this helps separate distinct regions that are connected by a narrow line and eliminate regions that are too small
9. Dilate the image.
   the number of times the image is dialed is typically chosen to be the same number of times the image was eroded
10. Further dilate the image.
   in this round, the image is dilated before being eroded
   helps remove cul-de-sacs, round edges, and combine regions that are very close together
11. Erode the image.
   the number of times the image is eroded is typically chosen to be the same number of times the image was dilated in the last step
12. Eliminate regions that are too close to the edge of the image.
   typically, it is deemed too close if any part of the regions is within (nerode+2) of the edge, where nerode is the number of times the image was eroded in step 9
   this eliminates regions that are only partially in the field of view
13. Fill in any holes in each region.
14. Eliminate regions with ECD (equivalent circular diameter)<2 sin(q₀)N₀/fov.
   q₀ and N₀ are parameter used in the curvature cutoff calculations.
   this eliminates regions that are small compared to the hemisphere with radius R
   these regions is likely to have slope variations within the region that is less than q₀
   another filter to consider in place of this one is to eliminate regions with standard deviations in the slope less than a cutoff value
15. Then calculate a new value for r.
   if number of peaks indentified equals zero then reduce r by two and round up
   go to step 4
   new r=round(f_{W}*L₀)
      f_{W} is a fixed parameter (typically ≦1), chosen before initiating the program
      L₀ is a length defined in Table A1
   if new r is less than r_{MIN}, set equal to r_{MIN}
   if new r is greater than r_{MAX}, set equal to r_{MAX}
   if r is unchanged or is repeated, this is the value for r that is chosen. Go to step 17.
   if coverage drops by a factor of Kc or more or if the number of regions increases by a factor of Kn or more, then the previous value for r is chosen. Go to step 17.
   if a value for r is not chosen, go to step 4.
16. For the r chosen, calculate the following dimensions for each region identified:
   ECD, L, W, and aspect ratio.
17. Calculate the mean and standard deviation for each dimension.
18. Calculate coverage and NN (Table A2).

TABLE A1
Definitions for parameters

| | |
|---|---|
| Δx | target step size that will be used in the slope calculations, actual step size is obtained |
| | by converting this to the nearest number of pixels |
| r | Δx rounded to the nearest number of pixels |
| f_{W} | new r = round(f_{W0} * L₀) |
| L₀ | length representing the typical size scale of the regions, distance between regions or |
| | diameter of curvature of the regions, whichever is smallest. L₀ = min (W₀, W₁, D₀). |
| W₀ | W₀ = f_{W0}*W + (1 − f_{W0})*L |
| W₁ | W₁ = W₀*(coverage^{-1/2} − 1) |
| D₀ | 10 percentile point for the diameter of curvature distribution (10% are less then this |
| | point) |
| f_{W0} | parameter used to calculate W₀ |
| f_{E} | the number of times the binary image is eroded = round(r * f_{E}) |
| f_{M} | parameter that impacts the size of the window for median averaging |
| rm_aspect_min | lower limit for the width to length ratio of the median averaging window |
| fov | length of the longest dimension of the field of view |
| ffov | Initially Δx is either chosen by the user or set equal to ffov * fov |
| | typical values for ffov are 0.01 and 0.015 |
| c0max | c0max = 2sin(q₀)N₀/fov curvature threshold for max(g-curvature, t-curvature) |
| c0min | c0min = −c0max curvature threshold for min(g-curvature, t-curvature) |
| N₀ | estimate of the least number of peak regions that is desirable to have across the |
| | longest dimension of the field of view |
| q₀ | estimate of the smallest slope (in degrees) that is of significance |
| r_{MIN} | r is not allowed to go below this value |
| r_{MAX} | r is not allowed to go above this value |
| Kc | If (new coverage) < (old coverage)/Kc then stop and keep old value for r |
| Kn | If (new number of regions) > (old number of regions) * Kn then stop and keep old |
| | value for r |

TABLE A2
Definitions for region dimensions

| | |
|---|---|
| ECD | equivalent circular diameter (ECD) of a region |
| L | length of major axis of the ellipse that has the same normalized second central moments |
| | as the region |
| W | length of minor axis of the ellipse that has the same normalized second central moments |
| | as the region |
| aspect ratio | W/L |
| NN | Equals one divided by the squareroot of the number of regions per unit area. Partial |
| | regions are included in this calculation. This is equal to the nearest neighbor distance |
| | between the center of the regions if the regions were arranged in a square lattice. |
| coverage | Equals the total area occupied by the regions divided by the total area of the image. |
| | Partial regions are included in this calculation. |

The dimensions were averaged over two height profiles.

Typical parameter settings were as follow:

| | |
|---|---|
| ffov | 0.015 |
| f_{W} | ⅓ |
| f_{M} | ⅔ |
| f_{E} | 0.3 |
| f_{W0} | ¾ |
| Kc | ½ |
| Kn | 2-4 |
| rmin | 2 |
| rmax | 50 |
| rm aspect min | ⅓ |
| N₀ | 4 |
| q₀ | ⅓-½ |

These parameter settings can be adjusted to insure that the major features (rather than minor features) are being identified.

### Height Frequency Distribution

The minimum height value is subtracted from the height data so that the minimum height is zero. The height frequency distribution is generated by creating a histogram. The mean of this distribution is referred to as the mean height.

### Roughness Metrics

Ra—Average roughness calculated over the entire measured array.

$$Ra = \frac{1}{MN} {\sum }_{i = 1}^{M} {\sum }_{k = 1}^{ N} \vert {Z}_{jk} \vert$$

wherein Zⱼₖ=the height of each pixel after the zero mean is removed.
   Rz is the average maximum surface height of the ten largest peak-to-valley separations in the evaluation area,

$$Rz = \frac{1}{10} [ ( {H}_{1} + {H}_{2} + … + {H}_{10} ) - ( {L}_{1} + {L}_{2} + … + {L}_{10} ) ] .$$

where H is a peak height and L is a valley height, and H and L have a common reference plane.

Each value reported for the complement cumulative slope distribution, peak dimensions, and roughness were based on an average of two areas. For a large film, such as a typical 43 cm (17 inch) computer display, an average of 5-10 randomly selected areas would typically be utilized.

### Diamond Design

A single crystal diamond tool with a radius of 500 μm (K&Y diamond, Montreal, Calif.) was modified using a Focused Ion Beam (FIB) microscope to have a multitude of subwavelength V-shaped teeth superimposed on the original radius as generally described in U.S. Pat. No. 7,140,812 (Bryan et al.). In the full nanostructure (FnS) design, the full working radius (approximately 50 um wide) was modified to have subwavelength V-shaped features (225 nm pitch, 225 nm tall triangular wave) on the diamond. In a second diamond tool, denoted the comparative structure diamond, no modification were made to the diamond radius edge.

### Materials

CN9893 is a difunctional aliphatic urethane oligomer obtained from Sartomer Company, Exton, Pa.
Dar 1173 is liquid benzoyl isopropanol available under the tradename DAROCUR 1173 from BASF, Florham Park, N.J.
Dar 4265 is a mixture of mixture of diphenyl-2,4,6-trimethyl benzoly phosphine oxide and 2-hydroxy-2-methyl-1-phenylpropan-1-one available under the tradename DAROCUR 4265 from BASF, Florham Park, N.J.
Desmolux XP 2513 is a urethane acrylate obtained from Bayer Material Science LLC, Pittsburgh Pa.
Exfluor 8FHDDA is octafluorohexanediol diacrylate obtained from Exfluor Research Corp., Round Rock, Tex.
Mitsubishi PET is primed PET available from Mitsubishi under the trade designation “4 mil Polyester film 0321 E100W76”.
PHOTOMER 6210 is an aliphatic urethane diacrylate obtained from Cognis Corporation, Cincinati, Ohio.
SR238 is 1,6 hexanediol diacrylate (HDDA) obtained from Sartomer Company, Exton, Pa.
SR444 is pentaerythritol triacrylate commercially available from Sartomer Company, Exton, Pa.
SR494 is ethoxylated pentaerythritol tetraacrylate obtained from Sartomer Company, Exton, Pa.

### Example 1 and Comparative Example

The full nanostructured diamond and comparative (i.e. without nanostructure) was used to cut a pattern into copper tooling with a pitch, P₁, of 14 microns and a maximum cutter width, P₂, of 46.15 microns. SEM images were taken of the nanostructures on the copper tool surface and these showed that the triangular wave pattern was reproduced with high fidelity with a pitch of about 240 nm.

Optical films comprising microstructured matte layers were made by microreplicating the patterned tools. Since the microstructured surface of the matte layer was a precise replication of the tool surface, the forthcoming description of the microstructured surface layer is also a description of the tool surface.

Handspread coatings were made using a rectangular microreplicated tool (4 inches wide and 24 inches long) preheated by placing them on a hot plate at 160° F. A “Catena 35” model laminator from General Binding Corporation (GBC) of Northbrook, Ill., USA was preheated to 160° F. (set at speed 5, laminating pressure at “heavy gauge”). The polymerizable resins were preheated in an oven at 60° C. and a Fusion Systems UV processor was turned on and warmed up (60 fpm, 100% power, 600 watts/inch D bulb, dichroic reflectors). Samples of polyester film were cut to the length of the tool (˜2 feet). A polymerizable resin, made by mixing 0.5% photoinitiator (Lucirin TPO from BASF) into an 75:25 blend of PHOTOMER 6210 and SR238, was applied to the end of the tool with a plastic disposable pipette, 4 mil (Mitsubishi 0321E100W76) primed polyester was placed on top of the bead and tool, and the tool with polyester run through the laminator, thus spreading the coating approximately on the tool such that depressions of the tool were filled with the polymerizable resin composition. The samples were placed on the UV processor belt and cured via UV polymerization. The resulting cured coatings were approximately 3-6 microns thick.

### Optical Properties for Example 1 and Comparative Example

Optical clarity values were measured using a Haze-Gard Plus haze meter from BYK-Gardiner (Silver Springs, Md.). Optical haze is typically defined as the ratio of the transmitted light that deviates from the normal direction by more than 2.5 degrees to the total transmitted light. Optical haze values were measured using the Haze-Gard Plus haze meter according to the procedure described in ASTM D1003.

Reflection (i.e. first surface specular reflection) of the microstructured antireflective films was measured using a Shimadzu UV-3101PC UN-VIS-NIR Scanning Spectrophotometer with the machine extension, MPC 3100, available from Shimadzu Co., Japan and Shimadzu Scientific Instruments, Columbia, Md. at an incident angle of 12° in reflection mode from 380 to 800 nm. The samples were mounted such that the nanostructures were substantially vertical in the spectrophotometer. These instruments measure the reflection of an area of about 1 cm². The reflection curve was plotted and the wavelength that the reflection was a minimum (LambdaMin) was recorded along with the minimum reflection (RMin). The average photopic reflectance (RPhotopicAvg) was also measured with the Shimadzu spectrophotometer. These values are reported in Table 2 along with the percent transmission, haze and clarity. The anti-glare (AG) property of the films was determined by inspection. LambdaMin, RMin and RPhotopicAvg were also determined for glass without film and this is reported in Table 2 for comparison.

TABLE 2

| | Lambda | | RPhotopic | | | | |
|---|---|---|---|---|---|---|---|
| | Min | RMin | Avg | % T | % H | % C | AG |
| Comparative | 0.00 | 3.51 | 4.06 | 94.30 | 2.13 | 85.90 | Yes |
| Example | | | | | | | |
| Example 1 | 610.72 | 1.21 | 1.26 | 96.90 | 1.20 | 72.00 | Yes |
| Comparative | 588.24 | 3.89 | 3.91 | | | | No |
| (glass w/o | | | | | | | |
| film) | | | | | | | |

### Resin Formulations

### Preparation of Fluoroacrylate/Multiacrylate (FA/MA) Formulation

A fluoroacrylate/multiacrylate formulation was prepared by mixing SR494 and Exfluor 8FHDDA in a 20:80 ratio by weight and adding 1.5 weight % Dar 1173 to the mixture.

### Preparation of SiO₂ Hardcoat (SiO₂/HC) Formulation

SiO₂ nanoparticles were surface modified with methacryloxypropyl trimethoxy silane, as described in PCT/US2007/068197. A SiO₂ hardcoat formulation was produced by mixing 48.75% surface modified SiO₂ nanoparticles with 48.75% SR444 and 2.5% Dar 4265.

### Preparation of Urethane Acrylate/Hexanediol Diacrylate (UA/HDDA) Formulation

A urethane acrylate formulation was prepared by mixing CN9893 and SR238 in a 70:30 ratio by weight and adding about 2-2.5% Dar 4265 to the mixture.

### Examples 2-4

Replication on the full nanostructured copper tool described in Example 1 was performed utilizing Mitsubishi PET with three other polymerizable resin compositions (described under Resin Formulations): a SiO₂/HC formulation (Example 2), a FA/MA formulation (Example 3), and a UA/HDDA formulation (Example 4). The same curing conditions as in Example 1 and a tool temperature of about 60° C. were used. Optical properties were measured as previously described and are reported in Table 3.

TABLE 3

| | | Lambda | | RPhotopic | | | |
|---|---|---|---|---|---|---|---|
| | Resin | Min | RMin | Avg | % T | % H | % C |
| Ex. 2 | SiO2/ | 630 | 1.22 | 1.25 | 94.7 | 1.27 | 73.6 |
| | HC | | | | | | |
| Ex. 3 | FA/ | 540 | 0.69 | 0.72 | 95.70 | 1.49 | 77.00 |
| | MA | | | | | | |
| Ex. 4 | UA/ | 556.22 | 1.03 | 1.06 | 95.10 | 2.03 | 72.80 |
| | HDDA | | | | | | |
| Comparative | | 703 | 3.87 | 3.89 | | | |
| (glass w/o | | | | | | | |
| film) | | | | | | | |

The Fcc was determined using a Wyko 10X Surface Profiler as described under “Microstructured Surface Characterization” and are reported in the following table.

TABLE 4

| Degrees | Example 4 |
|---|---|
| 0.1 | 99.0 |
| 0.3 | 95.2 |
| 0.7 | 82.3 |
| 1.3 | 57.0 |
| 2.5 | 18.4 |
| 4.1 | 4.5 |
| 6.1 | 1.33 |
| 8.1 | 0.2 |
| 10.1 | 0.03 |

### Example 5

Replication was performed on the full nanostructured copper tool described in Example 1 utilizing DuPont 2 side primed 5 mil “617” PET as a substrate. The resin was prepared by mixing 2% Dar 4265 into a 85:15 mixture of Desmolux XP 2513 and SR238. The resulting coating was 90 microns thick on top of the PET. Optical properties were measured as previously described and are reported in Table 5.

TABLE 5

| | | RPhotopic | | | |
|---|---|---|---|---|---|
| | R Min | Avg | % T | % H | % C |
| Ex. 5 | 1.10 | 1.15 | 96.0 | 1.72 | 72.7 |

1. An antireflective matte film comprising a microstructured surface layer comprising a plurality of microstructures having a complement cumulative slope magnitude distribution such that at least 30% have a slope magnitude of at least 0.7 degrees and at least 25% have a slope magnitude less than 1.3 degrees; wherein the microstructured surface or an opposing surface further comprises nanostructures.

2. The antireflective matte film of claim 1 wherein the nanostructures comprise a plurality of substantially parallel linear grooves.

3. The antireflective matte film of claim 2 wherein the nanostructures have an average pitch of less than 500 nm.

4. The antireflective matte film of claim 1 wherein the discrete peak microstructures have a mean equivalent circular diameter of at least 5 microns.

5. The antireflective matte film of claim 1 wherein the film has a clarity of at least 60%.

6. The antireflective matte film of claim 1 wherein the film has a haze of no greater than 10%.

7. The antireflective matte film of claim 1 wherein the antireflective film has an average photopic reflection of less than 2% at a wavelength of 550 nm.

8. The antireflective matte film of claim 1 wherein no greater than 50% of the microstructures comprise embedded matte particles.

9. The antireflective matte film of claim 1 wherein the microstructured surface is free of embedded matte particles.

10. (canceled)

11. The antireflective matte film of claim 1 wherein less than 15% of the microstructures have a slope magnitude of 4.1 degrees or greater.

12. (canceled)

13. The antireflective matte film of claim 1 wherein the film has an average roughness (Ra) of less than 0.14.

14. (canceled)

15. A microstructured article comprising a plurality of discrete peak microstructures having a complement cumulative slope magnitude distribution such that at least 30% have a slope magnitude of at least 0.7 degrees and at least 25% have a slope magnitude less than 1.3 degrees; wherein the microstructures have a complex shape.

16. The microstructured article of claim 15 wherein the nanostructures comprise a plurality of substantially parallel linear grooves.

17. The microstructured article of claim 16 wherein the nanostructures have an average pitch of less than 500 nm.

18. The microstructured article of claim 15 wherein the discrete peak microstructures have a mean equivalent circular diameter of at least 5 microns.

19. The microstructured article of claim 15 wherein the article is a light-transmissive film.

20. The microstructured article claim 15 wherein the film is a matte film.

21-22. (canceled)

23. A microstructured article comprising a plurality of discrete depressions corresponding to a negative replication of the plurality of peaks of claim 15.

24. The microstructured article of claim 23 wherein the microstructured article is a tool.

25-28. (canceled)

29. A method of making a microstructured article comprising:
providing a diamond tool wherein at least a portion of the tool comprises a plurality of tips wherein the pitch of the tips is less than 1 micron;
cutting a substrate surface with the diamond tool wherein the diamond tool is moved in and out orthogonal to the surface along a direction at a pitch (P₁) and the diamond tool has a maximum cutter width P₂ and P₂/P₁ is 2 to 15.

30-31. (canceled)
